(19) United States
(12) Patent Application Publication
(10) Pub. No.: US 2010/0176855 A1
(43) Pub. Date: Jul. 15, 2010

(54) PULSE WIDTH MODULATED CIRCUITRY FOR INTEGRATED DEVICES

(76) Inventors: James D. Huffman, Pittsford, NY (US); John A. Agostinelli, Rochester, NY (US)

Correspondence Address: Raymond L. Owens;Patent Legal Staff, Eastman Kodak Company, 343 State Street, Rochester, NY, 14650-2201, US

(21) Appl. No.: 12/352,034

(22) Filed: Jan. 12, 2009

(51) Int. Cl. H03K 5/01

(52) U.S. Cl. 327/166

(57) ABSTRACT

An apparatus for producing a separate pulse width modulation signal for each of a plurality of integrated devices, comprising circuitry for each integrated device having structures that :receive and convert a digital signal for each integrated device to an analog voltage level; sample the analog voltage level and storing such analog voltage level; and compare the stored analog voltage level to a common dynamic reference signal and producing a variable width pulse having a first level when the reference signal is above the analog voltage level and a second level when the reference signal is below the analog voltage level, wherein the common dynamic reference signal is the same signal for each integrated device

### FIELD OF THE INVENTION

This invention generally relates to device drivers for micro-electromechanical systems and more particularly relates to apparatus and methods for pulse-width modulation for systems that include an array of integrated devices.

### BACKGROUND OF THE INVENTION

Digital spatial light modulators (SLMs) are used to form images in a wide range of display, projection, and other imaging devices. A number of types of SLMs utilize arrays having one or more rows, each row having hundreds or thousands of tiny mechanically actuated devices. Each of the electromechanical devices is actuable to modulate incident illumination and provide modulated light for forming a portion of an image. For this type of digital spatial light modulator, common method for rendering different intensity levels is to use actuate individual electromechanical devices using pulse width modulation (PWM). A system using PWM divides up a fixed time interval, such as the frame refresh rate, into smaller blocks during which time the device is turned ON and OFF. The eye integrates these ON and OFF times to form an intermediate intensity level that is conventionally referred to as a grayscale. Studies have demonstrated that, for cinema-grade digital display systems, 14-bits of linear data are required to render the appropriate grayscale levels in an image.

With a display that system uses a full-frame spatial light modulator (SLM) such as the Digital Light Processor (DLP™), a type of digital micromirror device (DMD) from Texas Instruments, Inc., Dallas, Tex. With the DMD, each pixel in the image can use the full 16.667 msec to render its intensity level. Thus, at a refresh rate of 60 frames per second, a display system using a full-frame or area array SLM requires a PWM clock frequency of approximately 1 MHz, a realizable goal using conventional digital methods and components.

Display systems employing linear array SLMs such as the conformal grating device detailed by Marek W. Kowarz in commonly assigned U.S. Pat. No. 6,307,663, issued Oct. 23, 2001, entitled “SPATIAL LIGHT MODULATOR WITH CONFORMAL GRATING DEVICE,” present more demanding timing requirements than those of micromirror and other area arrays such as DMD devices. This is because the individual ribbons of the conformal grating device must operate at very high speeds compared to the modulation speeds needed for DMD devices.

The device of the Kowarz '663 disclosure has more recently become known as the conformal grating electromechanical system or GEMS device. In the conformal GEMS device, ribbon elements are suspended above a substrate by a periodic sequence of intermediate supports. In response to drive signals, electrostatic actuation causes the ribbon elements to conform around the support substructure, thereby producing a grating for light modulation. The GEMS device provides an advantageous alternative to other modulation components for progressive HDTV display systems and other applications.

The conformal GEMS device provides high-speed digital light modulation with high contrast and good efficiency. In addition, in a linear array of conformal GEMS devices, the active region is relatively large, allowing improved efficiency. With the GEMS device, the grating period is oriented perpendicular to the array direction. This orientation of the grating period causes diffracted light beams to separate in close proximity to the linear array and to remain spatially separated throughout most of an optical system and enables a simpler optical system design with smaller optical elements. Display systems based on a linear array of conformal GEMS devices were described by Kowarz et al. in commonly assigned U.S. Pat. No. 6,411,425, entitled “ELECTROMECHANICAL GRATING DISPLAY SYSTEM WITH SPATIALLY SEPARATED LIGHT BEAMS,” issued Jun. 25, 2002 and by Kowarz et al. in commonly assigned U.S. Pat. No. 6,476,848, entitled “ELECTROMECHANICAL GRATING DISPLAY SYSTEM WITH SEGMENTED WAVEPLATE,” issued Nov. 5, 2002.

Commonly assigned U.S. Pat. No. 6,717,714 entitled “METHOD AND SYSTEM FOR GENERATING ENHANCED GRAY LEVELS IN AN ELECTROMECHANICAL GRATING DEVICE” to Kowarz et al. describes how pulse-width modulation is used to provide a suitable number of gray levels with the GEMS device. To do this, pulse-width-modulated (PWM) waveforms are applied to the conformal GEMS devices of a linear array. FIG. 1 shows a conventional single-level PWM waveform 10 with voltage V_{HIGH}, together with the corresponding device's output (e.g., diffracted light intensity). To obtain a desired gray level, a controlling processor selects the voltage pulse width in each modulation window 12, according to the image data stream. When the single-level PWM waveform 10 transitions from 0 V to ±V_{HIGH}, the device actuates and begins diffracting light. When the waveform transitions back to 0 V, the device stops diffracting light. This process is applied to each conformal GEMS device of the linear array. In a typical display using the GEMS device, modulation window 12 corresponds to the time used to form a single line of the two-dimensional image. The gray level perceived in a pixel of the image is, therefore, the integrated light intensity within modulation window 12, as shown for a pulse 14 that is outlined in the example of FIG. 1. To minimize charging effects within the device, the applied voltage can be periodically switched between V_{HIGH} and −V_{HIGH} as shown here.

In response to the need for high-speed PWM processing with linear array devices, solutions using digital logic circuitry have been implemented. Intuitively, because the actuation of GEMS ribbon elements is a binary ON/OFF operation, the use of digital logic circuitry to control the state of GEMS ribbon elements makes sense. This same pattern also applies for other types of micro-electromechanical systems (MEMS) devices that have binary states. With GEMS, grating light valve (GLV), and similar devices, then, a fully digital data flow is thus used in conventional practice, from digital input data, to digital PWM pulse generation, to digital ribbon actuation. Conveniently, digital solutions can employ a number of CMOS (Complementary Metal-Oxide Semiconductor) fabrication techniques that are similar to fabrication methods that are used to form circuitry that supports the array of MEMS devices, such as those in the GEMS component itself.

Using fully digital methods to control PWM timing for each modulating element in an SLM array, a register is initially loaded with the desired digital timing value corresponding to the pulse width intended for the modulating element. Then, a counter is sequentially incremented and its digital value compared against the value loaded in the register. When the counter value reaches or exceeds the stored register value, the pulse is generated and ribbon actuation takes place. Decrementing the counter from its maximum value and repeating the comparison with each decrement then turns the pulse OFF after the desired interval.

However, as mentioned earlier, for linear array devices such as GEMS devices, GLV devices, and similar types of linear array SLMs, the needed data rate is considerably higher than that needed for DLP and other area arrays. With a GEMS projection display system that uses horizontal scanning of the image employing a one-dimensional array of GEMS devices, each pixel must render the required intensity level during, at most, only 1/n of the source data frame time, where n is the number of columns in the projected image. Further, the timing sequence must accommodate the overhead necessary for the scanning system to recover before displaying each next line of data. As an example, a scanning linear array SLM digital display system having 1920 columns has approximately a 20% retrace time. This would require a PWM processing clock of very high speed, approximately 2.4 GHz, in order to render the required 14-bits of linear grayscale data.

Commonly assigned U.S. Pat. No. 7,148,910 entitled “HIGH-SPEED PULSE WIDTH MODULATION SYSTEM AND METHOD FOR LINEAR ARRAY SPATIAL LIGHT MODULATORS” to Stauffer et al. describes a high-speed PWM solution that addresses this timing challenge using high-speed digital circuitry with phase-shifted clocking and other techniques. Even with solutions such as those proposed in the Stauffer et al. '910 disclosure, however, speed limitations continue to constrain the performance of GEMS and other linear array devices. Technical approaches of this type that may be suitable for providing 8-bit gray scale resolution become increasingly more difficult to implement as the resolution increases to 9-, 10-, or 11-bits. Beyond this level of grayscale resolution, digital components and techniques would not be expected to provide acceptable performance, cost, or speed.

In addition to requirements for high-speed signal propagation and processing, there are other design constraints that make it difficult to achieve high gray-scale resolution with GEMS and other linear array devices. One problem relates to circuit “real-estate”. For example, a significant amount of circuitry is required for PWM generation and control, with separate data registers, comparators, and driver logic required for each individual pixel of the GEMS device. Referring to FIG. 2, there is shown a block of circuitry for controlling the actuation of a number of GEMS pixel elements. A dashed-line box labeled block A shows, in block diagram form, the circuitry that is required for a single GEMS pixel element. This same set of components must be provided for each GEMS pixel element and is thus multiplied more than 1000 times for a single GEMS array. Even with component miniaturization, the amount of circuitry required for each GEMS pixel element is sizable and occupies an area larger than can readily be fit onto the same substrate, that is, packaged on the same integrated circuit chip that also contains the GEMS pixel elements. For this reason, the digital circuitry that is used to provide the functional elements for a single linear array of devices, such as that shown in FIG. 2, is provided as a separate component, such as an ASIC or other component, provided peripheral to the GEMS component.

Although separate component packaging for logic and driver components makes sense in terms of circuit real-estate, signal routing becomes a problem. With fully digital PWM control, extremely high signal and clock speeds must be transmitted between digital logic and GEMS components over very closely spaced traces or wires. Not only does space for running electrical signal traces or connecting wires become severely constrained; it also becomes complex and costly to correct for electromagnetic induction and other sources of signal noise when running, within a minimum area, thousands of circuit traces with high-speed signals.

Conventionally, analog-based methods of pulse-width modulation (PWM) are generally associated with larger components and circuits for driving motors and larger devices of various types, such as within a control loop. For this type of modulation, an analog voltage is accumulated over a time period, typically upon charging a storage capacitor, and the relative voltage level of this changing voltage measured against a reference threshold voltage. An ON/OFF pulse transition occurs each time the changing voltage from the charging or discharging storage capacitor transitions through the reference threshold voltage.

By contrast to analog methods, digital methods for PWM control are generally used in applications where reduced size, fast response, ease of implementation, and computing speed are of particular value, such as for actuation of binary devices. One practical advantage of digital PWM over analog approaches is that an incoming digital-level signal remains digital at each component as the signal is processed, without the need to convert the digital signal to a variable analog value. This can also be an advantage for reducing noise effects in some applications. Thus, for a number of good reasons, digital methods for PWM control are used with digital devices and for devices with binary (ON/OFF) states, such as MEMS devices, where an extra step of digital-to-analog conversion would not be advantageous. Among devices generally associated with digital control are those used in display applications that employ digital spatial light modulators, such as the full-frame digital micromirror device known as the Digital Light Processor (DLP) and the GEMS or other linear array device.

Thus, it is acknowledged that digital components and methods, while they offer advantages of miniaturization, ready programmability, and intuitive operation of binary ON/OFF actuation, are well suited to area arrays but impose some limitations on how quickly GEMS and other linear array devices can be driven and on how such devices are configured and packaged. These limitations, moreover, restrict the ability to take better advantage of increased device density, such as forming and using GEMS devices having two or three independently actuable GEMS arrays, for example.

### SUMMARY OF THE INVENTION

It is an object of the present invention to advance the art of modulation for electromechanical linear array modulators. With this object in mind, the present invention provides an apparatus for producing a separate pulse width modulation signal for each of a plurality of integrated devices, comprising circuitry for each integrated device having:

(a) means for receiving and converting a digital signal for each integrated device to an analog voltage level;

(b) means for sampling the analog voltage level and storing such analog voltage level; and

(c) means for comparing the stored analog voltage level to a common dynamic reference signal and producing a variable width pulse having a first level when the reference signal is above the analog voltage level and a second level when the reference signal is below the analog voltage level, wherein the common dynamic reference signal is the same signal for each integrated device.

It is a feature of the present invention that it employs a dynamic reference signal to control PWM timing of binary device actuation.

It is an advantage of the present invention that it reduces the amount of circuitry and space required for control of a linear electromechanical modulator in an array over conventional digital approaches.

These and other aspects, objects, features and advantages of the present invention will be more clearly understood and appreciated from a review of the following detailed description of the preferred embodiments and appended claims, and by reference to the accompanying drawings.

### BRIEF DESCRIPTION OF THE DRAWINGS

While the specification concludes with claims particularly pointing out and distinctly claiming the subject matter of the present invention, it is believed that the invention will be better understood from the following description when taken in conjunction with the accompanying drawings, wherein:

FIG. 1 is a timing diagram showing pulse timing and modulation windows for pulse-width modulation of a linear electromechanical grating device for light modulation;

FIG. 2 is a schematic block diagram showing components for PWM control of an array of linear modulator devices;

FIG. 3 is a schematic block diagram of a PWM drive circuit for an electromechanical ribbon modulator in one embodiment;

FIG. 4 is a timing diagram showing the timing of various digital and analog signals for the embodiment of FIG. 3;

FIG. 5 is a timing diagram that relates the dynamic reference signal to a pulse width;

FIG. 6 is a schematic block diagram showing an array of PWM drive circuits for a linear electromechanical ribbon modulator using an analog signal;

FIGS. 7A, 7B, and 7C show various timing arrangements for pulse-width generation using the methods and apparatus of the present invention; and

FIGS. 8A, 8B, and 8C show different configurations for fabrication of an integrated device.

### DETAILED DESCRIPTION OF THE INVENTION

The present description is directed in particular to elements forming part of, or cooperating more directly with, apparatus in accordance with the invention. It is to be understood that elements not specifically shown or described may take various forms well known to those skilled in the art.

For the description that follows, embodiments of the present invention are directed primarily to the task of modulation of a GEMS device. However, it should be noted that the same PWM apparatus and methods could be applied in a range of other applications for control of other MEMS devices, including light modulators, thermal print heads, and micro-fluidic devices as well as for arrays of optical emitters and other types of devices that use PWM actuation.

The method and apparatus of the present invention address the need for controlled actuation of microelectromechanical devices by replacing conventional digital PWM control methods with analog control techniques that are normally associated with control of larger devices. For each pixel in a GEMS device that includes several hundreds of pixels, this entails accepting a digital input value for the pixel, converting this digital input to an analog voltage value, comparing the converted analog voltage with a dynamic reference analog signal that is applied to all pixels in the GEMS array, and generating a resulting binary ON/OFF output driver signal that effects actuation or de-actuation of GEMS device ribbons corresponding to that pixel. Using this sequence, embodiments of the present invention adapt analog-referenced PWM techniques to the task of rapidly actuating miniature GEMS ribbon elements to binary ON/OFF positions in order to obtain pixels having variable gray scale levels. Although the apparatus and methods of the invention require transformation from binary signal handling, to analog signal handling, and back to binary drive signal generation, the analog control of embodiments of the present invention permits more compact packaging as well as operational advantages not otherwise available using conventional digital PWM control, including variable pulse-width centering and linearity adjustments, described in more detail subsequently.

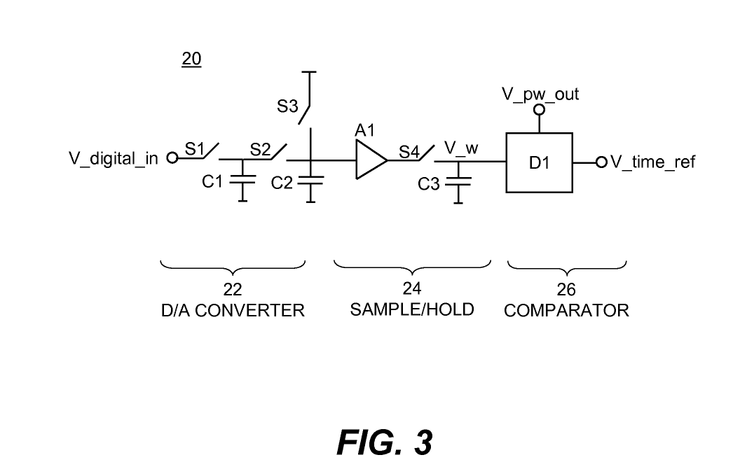

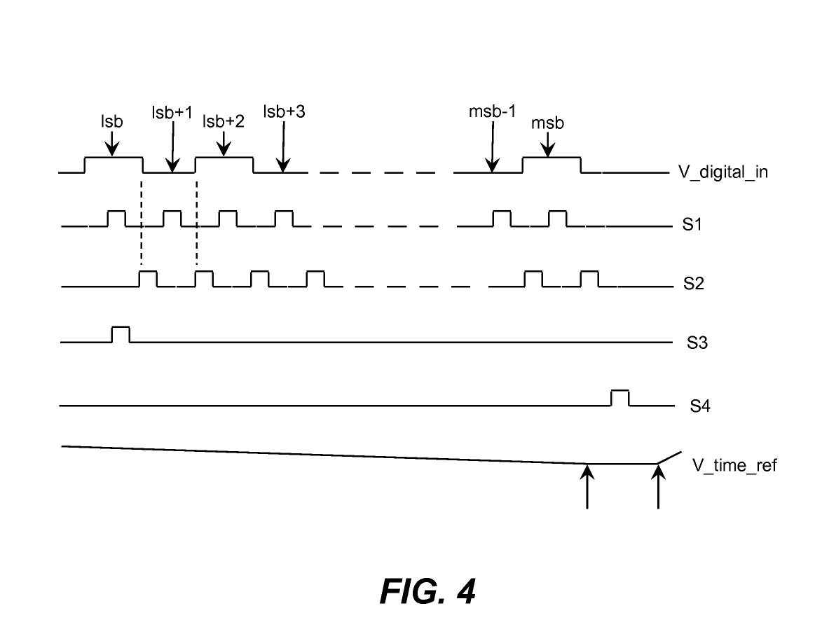

The schematic block diagram of FIG. 3 shows a representative PWM control circuit 20 for providing PWM output for controlling actuation of a single GEMS pixel element in one embodiment. PWM control circuit 20 has a digital-to-analog (D/A) converter 22, a sample-and-hold circuit 24, and a comparator 26. In FIG. 3, switches S1-S4 are all shown in an electrically “open” position. The graph of FIG. 4 shows timing of input and output signals relative to switch S1-S4 positions. Using the overall component arrangement of FIG. 3 and timing of FIG. 4, basic operation follows this repeated sequence:
(i) Charge generation at D/A converter 22. D/A converter 22 is used to receive a digital signal for each integrated pixel element and convert the digital signal to an analog voltage level. Signal V_digital_in provides an input serial signal with an encoded digital gray scale value of n bits, as shown in FIG. 4. This is the signal intended to specify the gray scale value that ultimately determines the width of the modulation pulse for the associated GEMS pixel element. In the embodiment described herein, the least significant bit (LSB) is provided first. Matched capacitors C1 and C2 sample the V_digital_in signal and provide signal averaging Switches S1 and S2 are alternately closed, once each for each bit of resolution, as shown in the timing chart of FIG. 4 in order to build charge and transfer charge voltage from capacitor C1 to capacitor C2. Reset switch S3 closes momentarily at the beginning of this cycle to discharge any residual voltage from capacitor C2 (at the input of linear amplifier A1 in the FIG. 3 schematic).
(ii) Charge storage using sample-and-hold circuit 24. At sample-and-hold circuit 24, linear amplifier Al provides unity amplification and stores the analog voltage signal from capacitor C2 as signal V_w in capacitor C3. Thus, the voltage level of signal V_w is the analog representation of the original digital signal for the pixel V_digital_in.
(ii) Voltage comparison at comparator 26. Signal V_w is then used as the threshold voltage for specifying the pulse-width interval, in cooperation with the common dynamic reference signal V_time_ref Comparator 26, typically a differential amplifier, compares the stored analog voltage level V_w to the common dynamic reference signal V_time_ref and produces, as output signal V_pw_out, a variable-width pulse having binary states: a first level when dynamic reference signal V_time_ref is above the analog voltage level V_w and a second level when the dynamic reference signal is below the analog voltage level V_w. The common dynamic reference signal V_time_ref is the same signal for each integrated device.

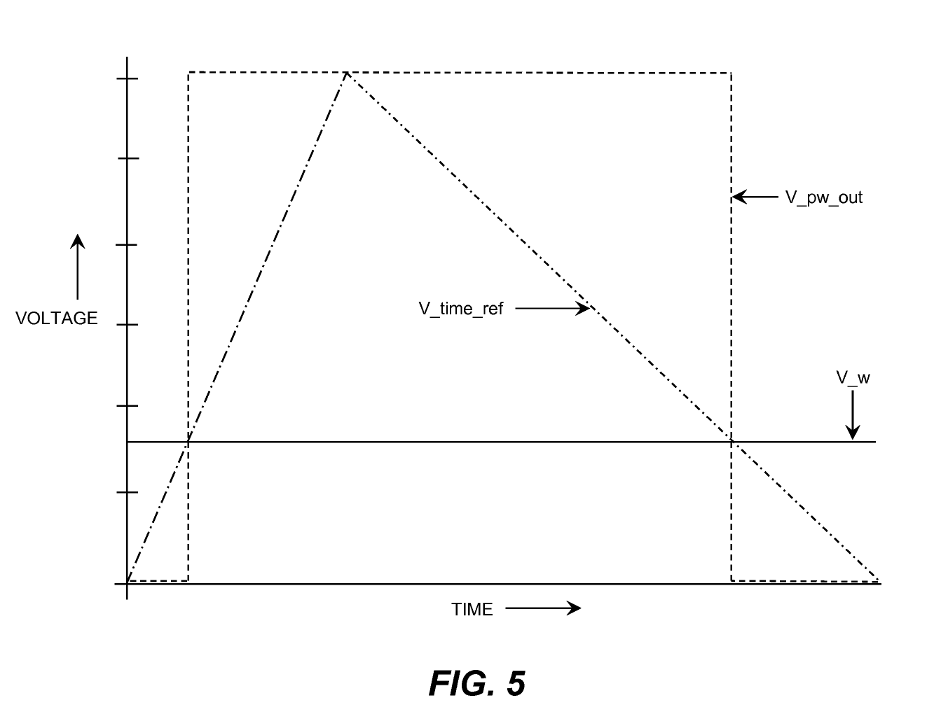

The graph of FIG. 5 shows the timing and voltage relationship between the dynamic reference signal V_time_ref and the generated analog signal V_w for forming a variable width pulse V_pw_out for modulation of a single pixel and how these two signals are used to determine the duration of the variable width pulse V_pw_out. In this figure, the dynamic reference signal V_time_ref appears as a linear ramp signal; however, waveform characteristics such as the shape of this signal and relative curvature of increasing and decreasing voltage portions can be varied as needed in order to provide a range of suitable PWM pulse characteristics.

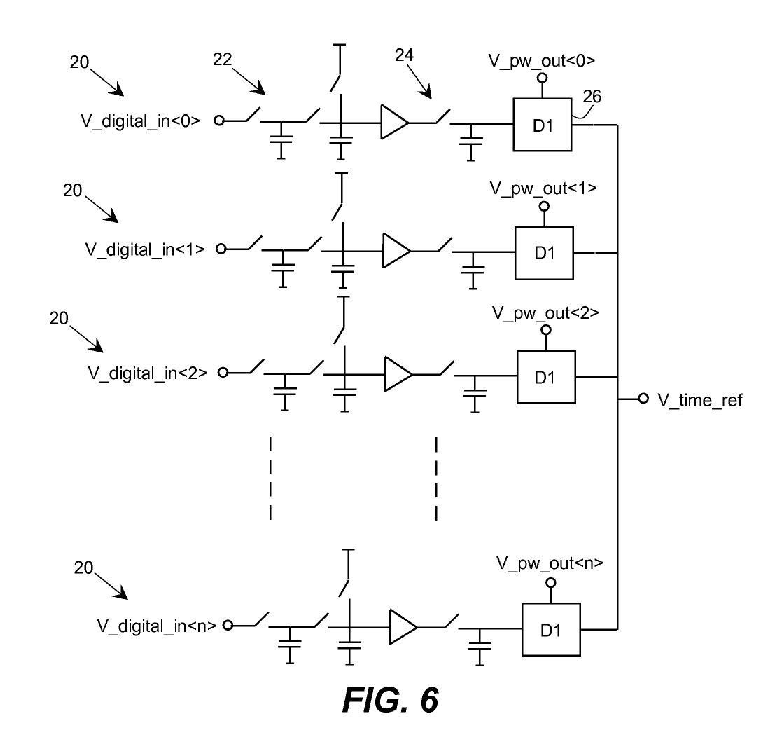

The schematic block diagram of FIG. 6 shows an array of n PWM control circuits 20 for n pixels, based on the pattern described with reference to FIG. 3. As this figure shows, the dynamic reference signal V_time_ref goes to each of the n PWM control circuits 20 as a common reference signal. Variable-width pulse signals V_pw_out<0>−V_pw_out<n>go to each respective integrated GEMS pixel element.

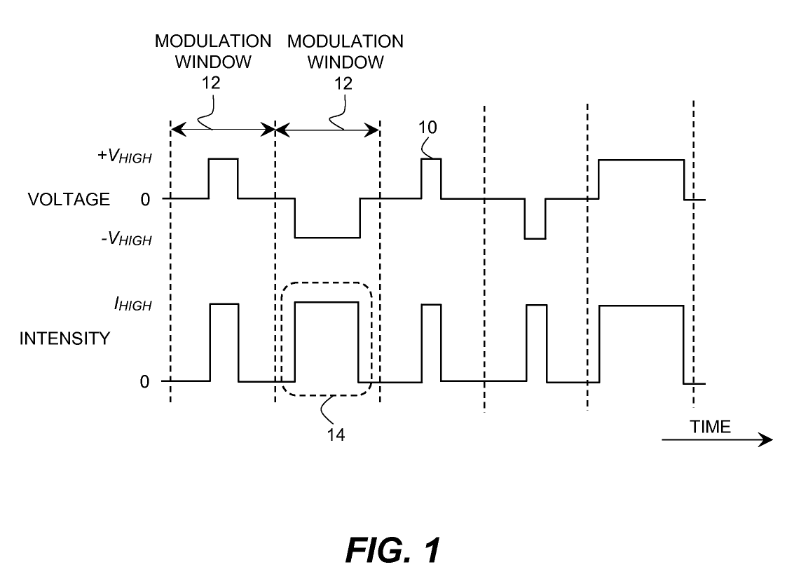

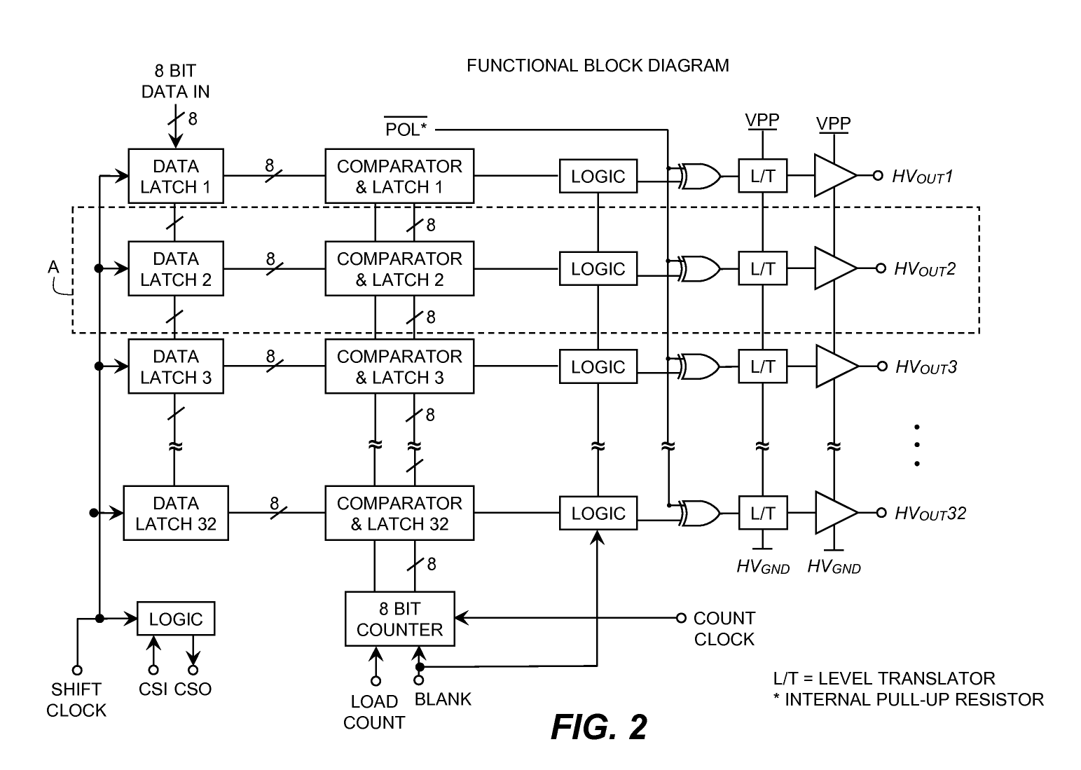

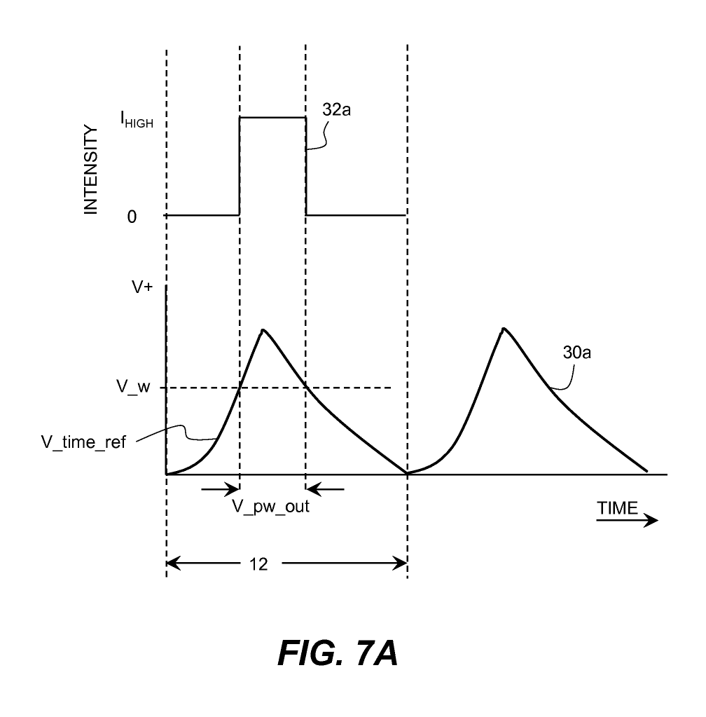

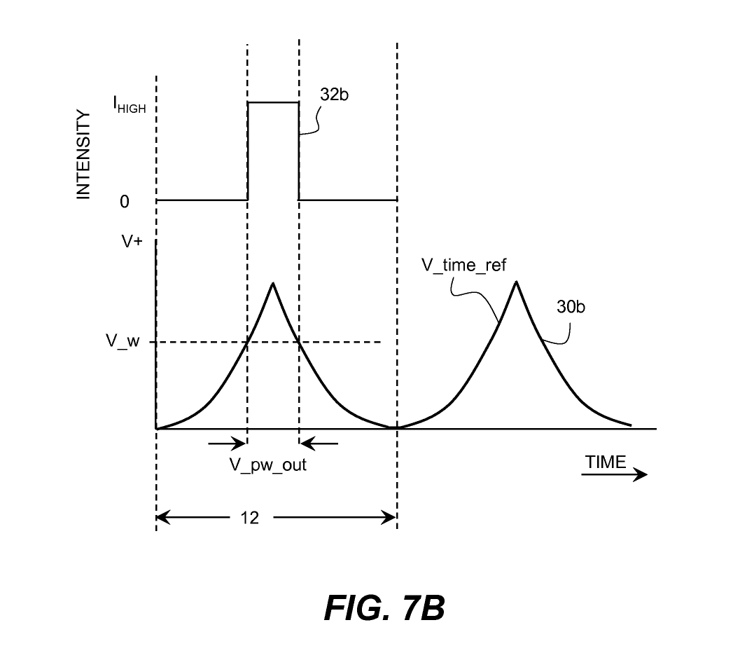

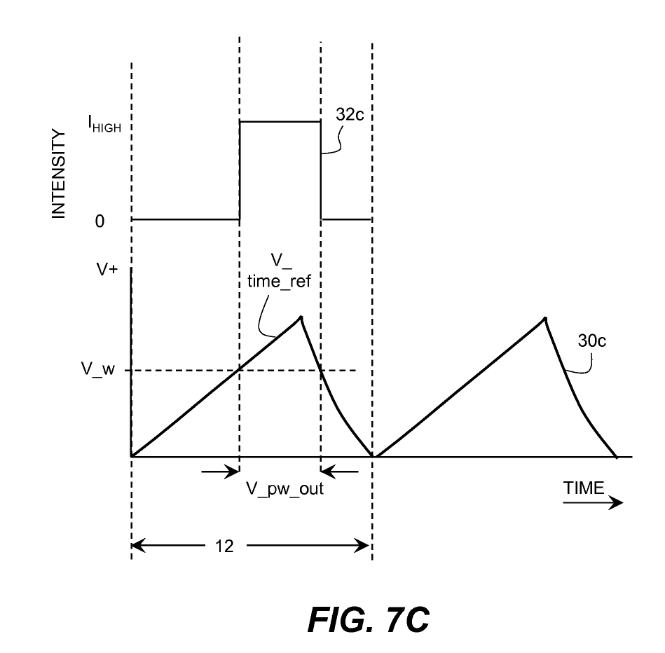

One particular advantage of the analog PWM driver of the present invention relates to varying not only the pulse width, but also the relative timing of the pulse within a modulation window as was described earlier with reference to FIG. 1. Referring to FIGS. 7A, 7B, and 7C, there are shown waveforms for three different common analog reference signals, dynamic reference signals 30a, 30b, and 30c respectively, corresponding to dynamic reference signal V_time_ref Each has a different waveform shape, provided, for example, by applying different RC time constants to the respective rising and falling portions of the dynamic reference signal V_time_ref using circuitry and techniques that are well-known to those in the circuit design arts. In FIG. 7A, dynamic reference signal 30a rises at a relatively fast rate, so that the generated PWM pulse 32a occurs at an early point in modulation window 12. In FIG. 7B, dynamic reference signal 30b rises and falls at a near constant rate, centering the generated PWM pulse 32b within the modulation window. In FIG. 7C, dynamic reference signal 30c has an extended rise time and a faster fall time, so that the generated PWM pulse 32c occurs at a later point within its modulation window 12. It can be appreciated that any number of analog V_time_ref signal shapes can be accommodated, including changing the peak voltage as well as changing the relative width and centering of the generated pulse. Symmetry of the dynamic reference signal V_time_ref is optional; the example V_time_ref waveforms shown in FIGS. 7A and 7C, for example, are substantially asymmetric about their peak value, such that the rising portion of the wavelength is not a mirror image of the falling portion. Multiple peaks can be provided for dynamic reference signal V_time_ref allowing more than one pulse to be generated within the same modulation window period. With reference to FIGS. 3A-3C, for example, this would mean the generation of one or more individual output pulses 32a-32c from within the same modulation window 12. This type of feature would not be straightforward to implement using conventional digital PWM generation methods.

Advantageously, dynamic reference signal V_time_ref is generated for multiple modulators, so that the drive circuitry for each modulator pixel (as in FIGS. 3 and 6) remains the same; only the dynamic reference signal generation circuit becomes more complex, changing the reference signal shape by various methods such as by switching in resistors of different values to effectively change the RC time constant. This arrangement, using a common dynamic reference signal, enables optimization of pixel actuation timing, such as relative to the refresh timing used in the display apparatus, for example.

It is instructive to compare the pulses 32a-32c generated in FIGS. 7A-7C with pulse 14 that is generated using conventional PWM methods in FIG. 1. Each pulse 14 in FIG. 1 is symmetrically centered within its modulation window 12. By comparison, pulses 32a-32c are each centered differently within their respective modulation windows 12; there is no requirement that the generated pulses 32a-32c be centered within window 12.

Timing control for variable PWM pulse centering, as shown in the examples of FIGS. 7A-7C, can be of particular value for controlling the spatial location of projected light from each line of pixels as it is scanned onto a display surface. By slightly varying this spatial position in successive scans, for example, a projection apparatus can compensate for various types of imaging problems, including some types of “screen door” pixellization effects, for example. This capability can be used, for example, to provide the shift of a line of pixels described in commonly-assigned copending patent application U.S. Ser. No. ______ filed concurrently herewith in the names of John R. Fredlund et al, entitled “Artifact Reduction in Optical Scanning Displays”.

The capability to control the functional dependence, including the use of non-linear segments of the V_time_ref waveform for PWM generation, enables control of the pixel input-output characteristic and can be used to compensate for device non-linearities, such as might be experienced with the GEMS device or other scanned spatial light modulator. Control of the input-output transfer characteristic can also be used to achieve a desired system response, for example, such as to provide a suitable tone scale for a display system.

As another advantage when using the PWM generation and timing method of the present invention, the gray scale bit depth for display applications no longer depends on the size or number of registers, as is the case with conventional digital PWM generation approaches. The incoming digital signal to each individual PWM control circuit, as shown in FIG. 3, can be of arbitrary bit depth. With reference to FIG. 4, for example, the bit depth of the gray scale can be increased simply by averaging additional digital bits as input. This serial approach alleviates the need to add additional circuitry for increased bit depth. Increasing the relative resolution of the gray scale merely means extending the timing that determines how many cycles the serial D/A uses before the sampling signal S4 is generated. For example, for a 12-bit gray scale, there are 12 cycles of averaging needed for signals S1 and S2. For a 14-bit gray scale, there are 14 cycles of averaging needed for signals S1 and S2. All of the same circuitry is used. By contrast, digital PWM schemes have a fixed upper limit for gray scale resolution, dependent on the amount of circuitry that is provided. A digital PWM circuit designed for 12-bit gray scale is not adaptable for a higher gray scale resolution. While it may be possible to use the same circuit for lower resolution, a portion of the circuitry is still present, but is unused.

### Fabrication

Component design for providing the analog circuitry of FIGS. 3 and 6 is well known. A standard CMOS mixed signal process can be used to fabricate the switches S1, S2, S3 and S4, as shown in FIG. 3, using NMOS and PMOS field effect transistors in a lossless pass gate configuration. The amplifier and comparator can be processed using the same CMOS components using standard analog design practices. The capacitors C1, C2 and C3 can be fabricated in the same process using gate capacitors or by using standard poly-2 and poly-1 fabrication techniques, familiar to those skilled in the component fabrication arts.

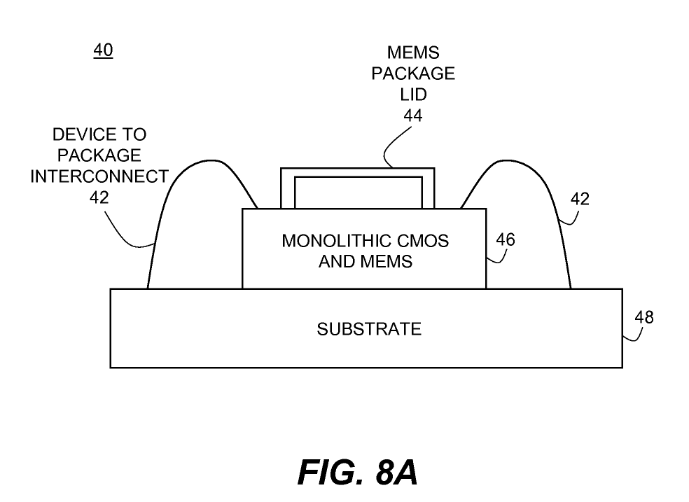

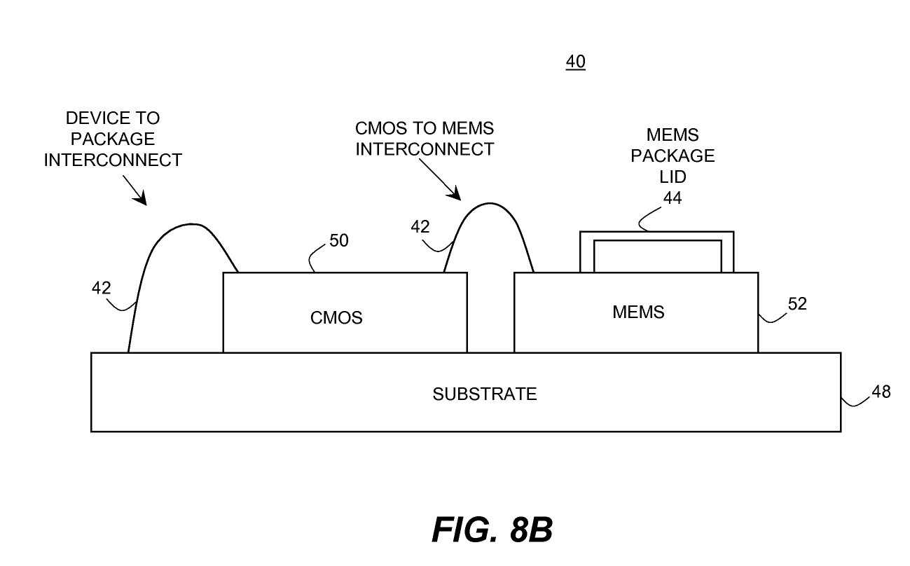

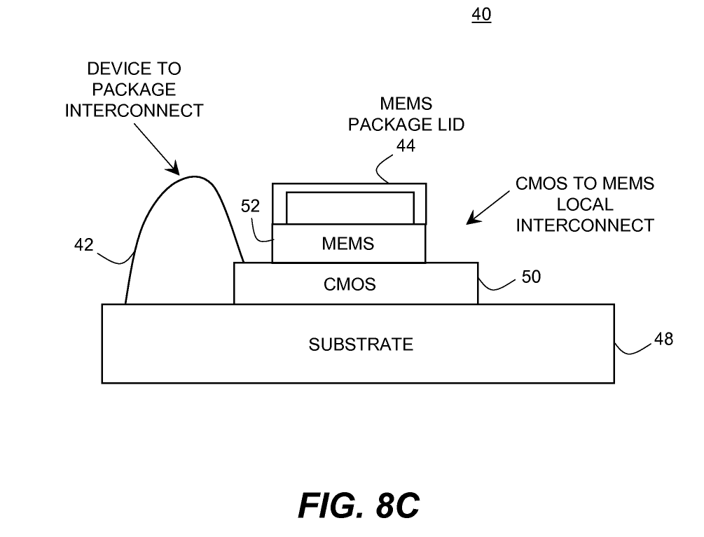

Similarly, fabrication methods that can be used to implement an integrated device are standard in the semiconductor industry. The integration of the GEMS pixels with the PWM control circuitry of embodiments of the present invention can be performed using any of several different fabrication methods, shown in the schematic block diagrams of FIGS. 8A, 8B, and 8C. In the monolithic integration embodiment of FIG. 8A, a GEMS or other type of integrated MEMS device 40 is monolithically processed as a continuation of the CMOS mixed signal process. In the FIG. 8A embodiment, a monolithic element 46 contains both CMOS and MEMS components and is provided on a substrate 48 with interconnects 42 for package connection. A MEMS package lid 44 can be provided, such as would be needed for the GEMS ribbon array, for example. This method of integration parallels techniques that have been conventionally used for micromirror array fabrication, for example.

FIG. 8B shows an embodiment of integrated MEMS device 40 using multichip modules (MCM). A CMOS module 50 is fabricated and then bonded onto substrate 48. A MEMS module 52 is separately fabricated and bonded onto substrate 48. Interconnects 42 are then provided between modules 50 and 52 and between the CMOS circuitry and external interconnects for the combined package.

FIG. 8C shows an embodiment of integrated MEMS device 40 arranged with System-In-Package (SIP) structure. For this configuration, CMOS module 50 is fabricated and then bonded onto substrate 48. MEMS module 52 is separately fabricated and mounted onto CMOS module 50. Vias or other internal connections are provided between MEMS module 52 and CMOS module 50.

Thus, using the analog PWM circuitry arrangement described with reference to FIGS. 3-6, control circuits for pulse-width controlled GEMS pixel element actuation can be provided on the same substrate that also contains the electromechanical actuator ribbons for a GEMS or similar linear array. This eliminates the need for having PWM control circuitry located on auxiliary interface circuits, with the need for extensive signal routing to the GEMS chip, as is currently done with conventional digital PWM generation. The arrangements of FIGS. 8A-8C can also allow multiple GEMS arrays to be formed on the same substrate, so that a bilinear or trilinear GEMS device can be fabricated without the need for routing PWM control signals from external components to individual elements on the GEMS device.

The PWM control apparatus of the present invention has been described for embodiments that control the binary ON/OFF state of a GEMS modulator pixel, with multiple PWM control apparatus provided for an integrated array of GEMS modulator pixels. It can be appreciated that this apparatus and method can also be extended to control the operation of any of a number of other types of integrated devices, particularly where these devices are miniaturized and component real-estate is limited. Advantageously, the PWM control circuitry can be provided on the same substrate that provides the GEMS modulation ribbon or other type of integrated device.

The invention has been described in detail with particular reference to certain preferred embodiments thereof, but it will be understood that variations and modifications can be effected within the scope of the invention as described above, and as noted in the appended claims, by a person of ordinary skill in the art without departing from the scope of the invention. For example, there are a number of ways to generate the V_time_ref signal that serves multiple PWM control circuits 20 (FIG. 6). The V_time_ref signal can be changed with time, such as to adjust for ageing over the life of the GEMS circuit or may be adjusted for a particular display as part of a calibration process.

Thus, what is provided is an apparatus and method for pulse-width modulation for systems that include an array of integrated devices.

### PARTS LIST

10 PWM waveform
12 Modulation window
14 Pulse
20 PWM control circuit
22 D/A converter
24 Sample-and-hold circuit
26 Comparator
30a, 30b, 30c Dynamic reference signal
32a, 32b, 32c PWM pulse
40 Integrated MEMS device
42 Interconnect
44 Lid
48 Substrate
50 CMOS module
52 MEMS module
V_digital_in Digital gray scale value
V_pw_out Timed pulse width
V_time_ref Ramp voltage
V_w Analog representation of V_digital_in
V+ Voltage
A Block

1. an apparatus for producing a separate pulse width modulation signal for each of a plurality of integrated devices, comprising circuitry for each integrated device having:
(a) means for receiving and converting a digital signal including a serial digital to analog converter for each integrated device to an analog voltage level, wherein the digital signal is a serial signal of arbitrary bit depth;
(b) means for sampling the analog voltage level and storing such analog voltage level; and
(c) means for comparing the stored analog voltage level to a common dynamic reference signal and producing a variable width pulse having a first level when the reference signal is above the analog voltage level and a second level when the reference signal is below the analog voltage level, wherein the common dynamic reference signal is the same signal for each integrated device.

2. The apparatus of claim 1 where the digital signal represents a gray scale level.

3. The apparatus of claim 1 further including a substrate and wherein the integrated devices and the circuitry for each device are integrated on the substrate.

4. (canceled)

5. The apparatus of claim 1 wherein the sampling means includes a storage capacitor for storing the analog voltage level.

6. The apparatus of claim 1 wherein the comparing means includes a differential amplifier that compares the common dynamic reference signal with the stored analog voltage level.

7. The apparatus of claim 1 wherein the integrated devices include light modulators, thermal print heads, or micro-fluidic devices.

8. (canceled)

9. The apparatus of claim 1 further comprising means for adjusting the waveform of the dynamic reference signal.

10. A method for actuating each of a plurality of integrated devices comprising:
(a) receiving a digital signal for each integrated device and converting the digital signal to an analog voltage level;
(b) storing the analog voltage level for each integrated device;
(c) generating a common dynamic reference signal for the plurality of integrated devices comprises generating a waveform having non-linear segments for controlling the output behavior of the integrated device; and
(d) comparing the stored analog voltage level for each integrated device with the common dynamic reference signal and generating a pulse within a modulation window according to the relative values of the stored analog voltage level and the common dynamic reference signal.

11. The method of claim 10 wherein generating the common dynamic reference signal comprises adjusting the waveform shape for changing the center of the pulse within the modulation window.

12. (canceled)
